(19) United States
(12) Patent Application Publication
(10) Pub. No.: US 2015/0179894 A1
(43) Pub. Date: Jun. 25, 2015

(54) METHODS OF LOCATING DIFFERENTLY SHAPED OR DIFFERENTLY SIZED LED DIE IN A SUBMOUNT

(71) Applicant: GLO AB, Lund (SE)

(72) Inventors: Scott Brad Herner, San Jose, CA (US); Linda Romano, Sunnyvale, CA (US); Daniel Bryce Thompson, Walnut Creek, CA (US); Martin Schubert, Sunnyvale, CA (US); Ronald Kaneshiro, Los Altos, CA (US)

(21) Appl. No.: 14/549,826

(22) Filed: Nov. 21, 2014

Related U.S. Application Data
(60) Provisional application No. 61/907,528, filed on Nov. 22, 2013.
(60) Provisional application No. 61/930,070, filed on Jan. 22, 2014.
(60) Provisional application No. 61/971,586, filed on Mar. 28, 2014.

(51) Int. Cl. H01L 33/48; H01L 27/15

(52) U.S. Cl. CPC H01L 33/483; H01L 27/153; H01L 2933/0033

(57) ABSTRACT

Methods of locating a plurality of light emitting diode (LED) dies in a submount include providing the plurality of LED dies across a surface of the submount, the submount including a plurality of tubs corresponding in shape and/or size with the shape and/or size of the LED dies to fill each tub with correspondingly shaped and/or sized LED die.

### FIELD

The embodiments of the invention are directed generally light emitting diodes (LED), and specifically to locating differently shaped or differently sized LED die in a submount.

### BACKGROUND

LEDs are used in electronic displays, such as liquid crystal displays in laptops or LED televisions. Conventional LED units are fabricated by mounting LEDs to a substrate, encapsulating the mounted LEDs and then optically coupling the encapsulated LEDs to an optical waveguide.

Typically, numerous LEDs are fabricated simultaneously on a single wafer and then the wafer is diced to form individual LEDs. When dicing the individual LEDs from a sapphire substrate, the sapphire substrate is thinned to approximately 100 um and then etched or mechanically scratched to create scribe marks for a subsequent break step using an anvil. Alternatively, the scribe marks may be formed with a laser.

Fabricating individual LEDs using the conventional dicing methods may result in damage to the wafer and the LEDs. For example, a continuous GaN layer on a sapphire substrate imparts a compressive stress on the underlying sapphire substrate which can affect the curvature of the substrate and may lead to undesired breakage of the substrate and destruction of the LEDs on the substrate.

### SUMMARY

One embodiment provides a method of locating a plurality of light emitting diode (LED) dies in a submount including providing a submount having first tubs having at least one of a first tub shape or a first tub size, and second tubs having at least one of a second tub shape or a second tub size different from the respective first tub shape or first tub size, providing a first plurality of LED die having at least one of a first die shape or first die size to locate across the submount the first plurality of LED die in the first tubs but not in the second tubs and providing a second plurality of LED die having at least one of a second die shape or second die size to locate across the submount the second plurality of LED die in the second tubs but not in the first tubs.

Another embodiment provides a method of locating a plurality of asymmetrically shaped light emitting diode (LED) dies in a submount including depositing the plurality of LED dies on a surface of the submount, the submount comprising a plurality of asymmetric tubs corresponding in shape with the asymmetrically shaped LED dies and vibrating the submount to located the plurality of LED dies in respective asymmetric tubs.

Another embodiment provides a light emitting diode device comprising a plurality of asymmetrically shaped light emitting diode (LED) dies located in a submount in a plurality of asymmetric tubs corresponding in shape with the asymmetrically shaped LED dies.

Another embodiment provides a method of locating a plurality of differently shaped or differently sized light emitting diode (LED) die in a submount includes providing a first plurality of LED die of a first size or shape suspended in a fluid flowing across the submount to locate the first plurality of LED die of the first size or shape in respective first tubs in a surface of the submount, the first tubs having a first size or shape, and after the step of providing the first plurality of LED die, providing a second plurality of LED die of a second size or shape suspended in a fluid flowing across the submount to locate the second plurality of LED die of the second size or shape in respective second tubs in the surface of the submount, the second tubs having a second size or shape.

Another embodiment is drawn to a method of locating a plurality of asymmetrically shaped light emitting diode (LED) dies in a submount including providing the plurality of asymmetrically shaped LED die suspended in a fluid flowing across the submount to locate the plurality of asymmetrically shaped LED die in a plurality of asymmetric tubs corresponding in shape with the plurality of asymmetrically shaped LED die.

Another embodiment is drawn to a method of serially locating a plurality of differently shaped or differently sized light emitting diodes (LED) die in a submount including depositing a first plurality of differently shaped or differently sized LED die on a surface of the submount, the submount comprising a plurality of first shaped or differently sized tubs corresponding in shape with the first plurality of differently shaped or differently sized LED die, vibrating the submount to locate the first plurality of differently shaped or differently sized LED die in the first differently shaped or differently sized tubs, after the step of vibrating the submount to locate the first plurality of differently shaped or differently sized LED die in the first differently shaped or differently sized tubs, depositing a second plurality of differently shaped or differently sized LED die on a surface of the submount, the submount comprising a plurality of second shaped or differently sized tubs corresponding in shape with the second plurality of differently shaped or differently sized LED die and vibrating the submount to locate the second plurality of differently shaped or differently sized LED die in the second differently shaped or differently sized tubs.

### BRIEF DESCRIPTION OF THE DRAWINGS

FIGS. 1A and 1B are schematic illustrations of a plan view and a side cross-sectional view, respectively, of a LED device with a square planar cross section.

FIGS. 1C and 1D are schematic illustrations of a plan view and a side cross-sectional view, respectively, of a LED device with a hexagonal planar cross section.

FIG. 2 is a plot of the reflection coefficient as a function of the angle of incidence for the LEDs of FIGS. 1A-1D.

FIG. 3A is a schematic illustration of a top view of a rectangular shaped LED die with symmetry about the x and y axis; FIG. 3B is a schematic illustration of a top view of an asymmetric die according to an embodiment.

FIGS. 4A-4D are a schematic illustration of a plan view of steps in a method of singulating LED dies.

FIGS. 5A-5E are schematic illustrations showing the steps in methods of singulating LED dies according to an embodiment of the invention.

FIG. 6 is a photograph of a singulated LED die.

FIG. 7 is a perspective illustration of a submount according an embodiment.

FIG. 8 is a plan view of a submount according to another embodiment.

FIG. 9 is schematic illustration of a cross-sectional view of the submount of FIG. 8 through line AA.

FIG. 10 is schematic illustration of a cross-sectional view of the submount of FIG. 9 through line BB.

FIG. 11 is a three dimensional cut away view illustrating a portion of the submount of FIG. 8.

FIGS. 12A-12D are perspective views illustrating a method of locating LED dies in a submount according to an embodiment.

FIG. 13 is a side cross-sectional view illustrating a step in the method of FIGS. 12A-12D.

### DETAILED DESCRIPTION

The present inventors realized that prior art methods of singulating or dicing semiconductor devices, such as LED dies from substrates, such as wafers, may result in damage to the wafer and the singulated LEDs. The present inventors have also realized that LED devices may be advantageously fabricated with the use of a semiconductor submount, such as a silicon submount with integrated interconnects in the submount. The present inventors have further realized that the fabrication of LED devices having large numbers of LEDs, such as thousands, such as tens of thousands, such as hundreds of thousands, such as millions, such as tens of millions, may be efficiently and inexpensively fabricated with the use of differently shaped or differently sized LED dies, including asymmetrically shaped dies. In an embodiment, the first color (e.g., red) LED dies have a first asymmetrical shape, the second color (e.g., green) LED dies have a second asymmetrical shape and the third color (e.g., blue) LED dies have a third asymmetrical shape, where the first, second and third shapes are different from each other. In an embodiment, the submount comprises asymmetrical tubs which correspond to the asymmetrical LED dies. In another embodiment, the submount may be vibrated to aid in locating the asymmetrical LED dies into the asymmetrical tubs in the submount.

Compressive stresses up to 1 GPa may develop in planar GaN films grown on sapphire substrates depending on the thickness of the GaN film, the growth temperature and the dislocation density in the GaN film. Due to the lattice mismatch between the sapphire substrate and the III-V and or II-VI compound semiconductor materials of the LED nanowire materials used in nanowire LED devices, the nanowire LEDs are typically not directly grown on the sapphire substrates. Rather the LED nanowires are grown on a continuous GaN film deposited on the sapphire substrate. Thus, both planar and nanowire LED devices can be fabricated on sapphire substrates.

However, as discussed above, the amount of stress in the underlying GaN film can affect the curvature of the wafer and in some cases lead to wafer breakage. Thus, in conventional scribe/break methods typically used to create GaN LED devices, wafer breakage should be carefully managed. Typically, the sapphire substrate is thinned to approximately 100 um and mechanically scratched or etched to create scribe marks for the subsequent break step using an anvil.

In some cases, mechanical dicing methods have been replaced by lasers. Laser scribing reduces breakage and allows for narrower dicing streets. This ultimately increases the die yield and the number of dies/wafer.

Another advantage of a laser is that the power and focus can be controlled to manage the depth of the scribe. The inventors have realized that is property of the laser can be combined with the compressive stress in the GaN films on the sapphire nanowires to create alternative device geometries that would be difficult to achieve by conventional laser scribe/break methods. In another embodiment, the anvil breakage step may be replaced with a roller breaker process.

In an embodiment, streets are patterned through the LED device layers on a completed wafer of dies and etched from the top side of the wafer to the sapphire substrate. Device geometries can include conventional shapes, such as squares or low-aspect ratio rectangles, as well as high-aspect ratio geometries, non-rectangular shapes, or shapes for which the convex hull of perimeter points is larger than the total shape area. High-aspect-ratio geometries are suitable for extremely compact packages and are desirable, for example, for backlighting applications.

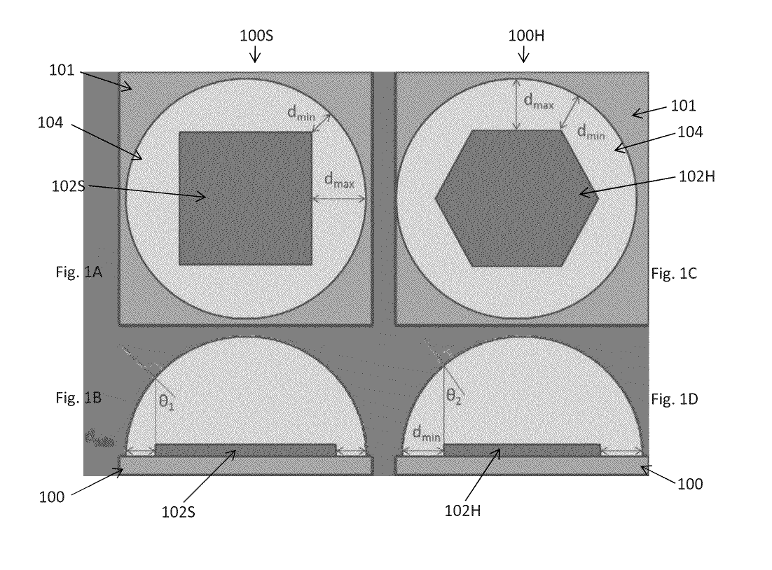

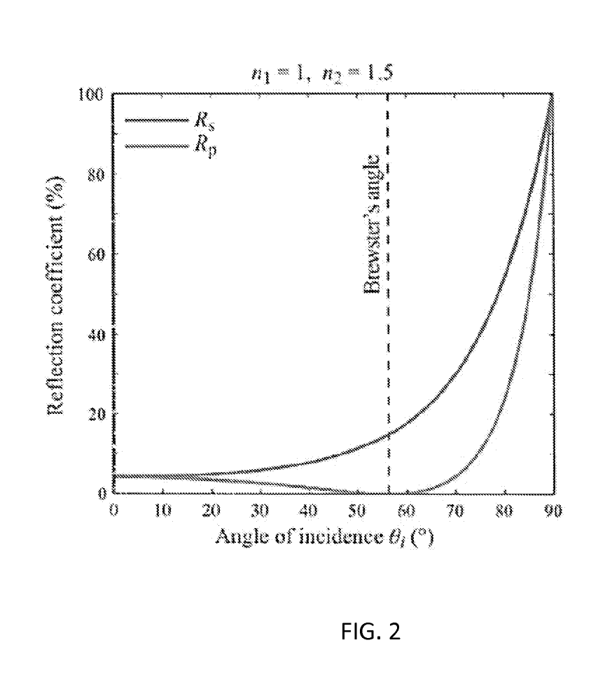

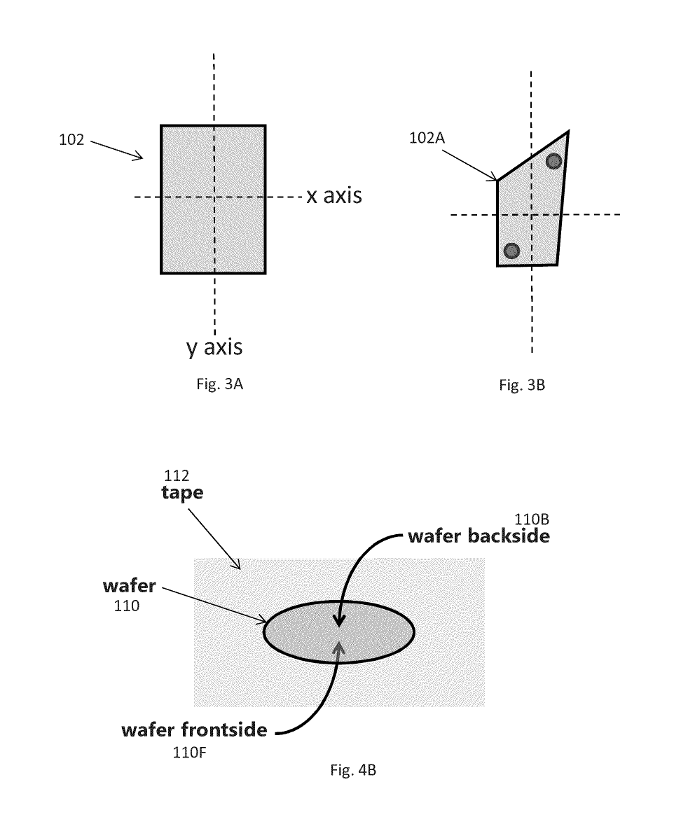

In an embodiment, non-rectangular shapes include shapes which may be more circular than rectangular in character, e.g. hexagons, which in a package (device) 100 having a dome lens 104 yields improved package-level extraction efficiency compared to a square die with the equivalent area as illustrated in FIGS. 1A-1D and 2. FIGS. 1A and 1B are schematic illustrations of a plan view and a side cross-sectional view, respectively, of a LED device 100S which includes a LED die 102S with a square planar cross section. FIGS. 1C and 1D are schematic illustrations of a plan view and a side cross-sectional view, respectively, of a LED device 100H which includes a LED die 102H with a hexagonal planar cross section. In both cases, the LED dies 102S, 102H are located on a substrate 101 and covered with a transparent, dome shaped lens 104.

In the embodiments, illustrated in FIGS. 1A-1D, the surface areas of the top surfaces of the LED dies 102S, 102H are the same. As illustrated in FIGS. 1A-1D, when the surface areas of the LED dies 102S, 102H are the same, the minimum distance dₘᵢₙ from the hexagonal LED die 102H to the edge of the lens 104 is less than the minimum distance dₘᵢₙ from the square LED die 102S to the edge of the lens 104. As a consequence in the difference in the minimum distance dₘᵢₙ, the incident angles θ₂ for light emitted from edges of the hexagonal LED die 102H tend to be smaller than the incident angles θ₁ for light emitted from edges of the square LED die 102S. This results is a smaller reflection coefficient. Therefore, light extraction efficiency will be greater for a LED device 100H with a hexagonal LED versus a LED device 100S with a square LED die 102S with the same light emitting surface area.

FIG. 2 compares the reflection coefficient as a function of the angle of incidence for the LED devices 100S, 100H illustrated in FIGS. 1A-1D. As illustrated in FIG. 2, the reflection coefficient R_{P} for the LED device 100H with the hexagonal LED die 102H is lower than the reflection coefficient R_{S} for the LED device 100S with the square LED die 102S for all angles between 10° and 90°.

The improved package-level extraction efficiency is due to the reduction of emission into low-extraction modes approaching whispering gallery modes, e.g., light emitted from the corners of a square die. In addition, the projected beam from such a die has a more circular character, which is beneficial for lighting applications. Similarly, alternative geometries, e.g. triangles, improve die-level extraction efficiency due to the reduction of whispering gallery modes. Other sophisticated shapes may also be beneficial for forming tightly-packed LED arrays incorporating different die types.

In an embodiment, pulsed laser methods are used to form a defect pattern under the bottom side of the wafer which mimics the top surface street pattern. The laser is focused to a point internal to the wafer substrate, away from the LED device. In an embodiment, a roller is then used to separate the damaged wafers.

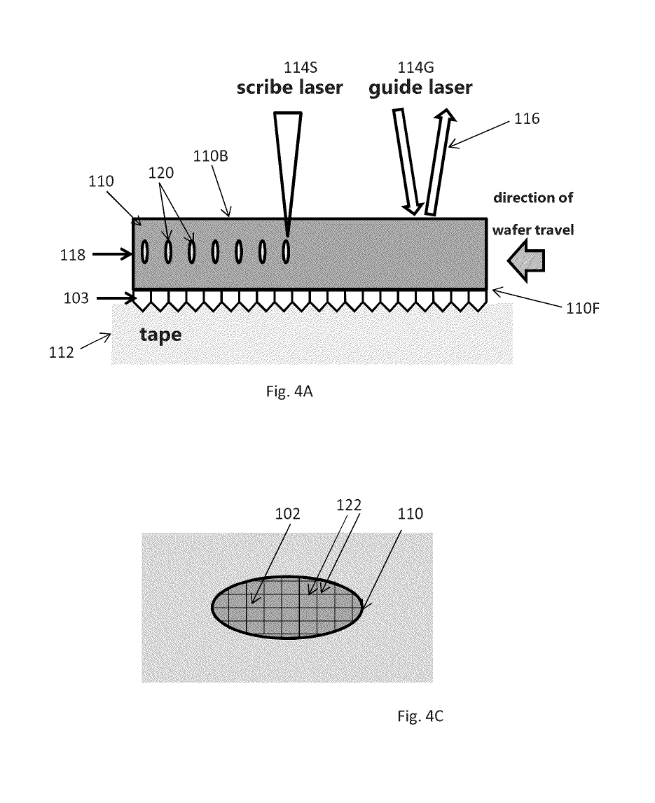

FIG. 3A illustrates a top view of a rectangular shaped die with symmetry about the x and y axis. Standard singulation techniques involving thinning and then mechanically sawing wafers results in dies 102 that are symmetric about the x and y axes as shown in FIG. 3A. Symmetry of an object is defined as the object having a mirror image across the line of the axis.

FIG. 3B illustrates an asymmetrically shaped die which may be fabricated according to the methods described below. As described in more detail below, asymmetrically shaped dies may be located in corresponding differently asymmetrically shaped tubs on a submount. In this manner, LEDs that emit light at of preselected wavelength/color may be uniquely located or arranged in a preselected pattern in a submount. Alternatively, the dies may have different but symmetric shapes (e.g. circles, squares, rectangles, hexagons, etc.). Alternatively, different dies may have the same shape (symmetric or asymmetric) but have different sizes (e.g. red light emitting dies have the smallest size, green emitting dies have an intermediate size and blue emitting dies have the largest size).

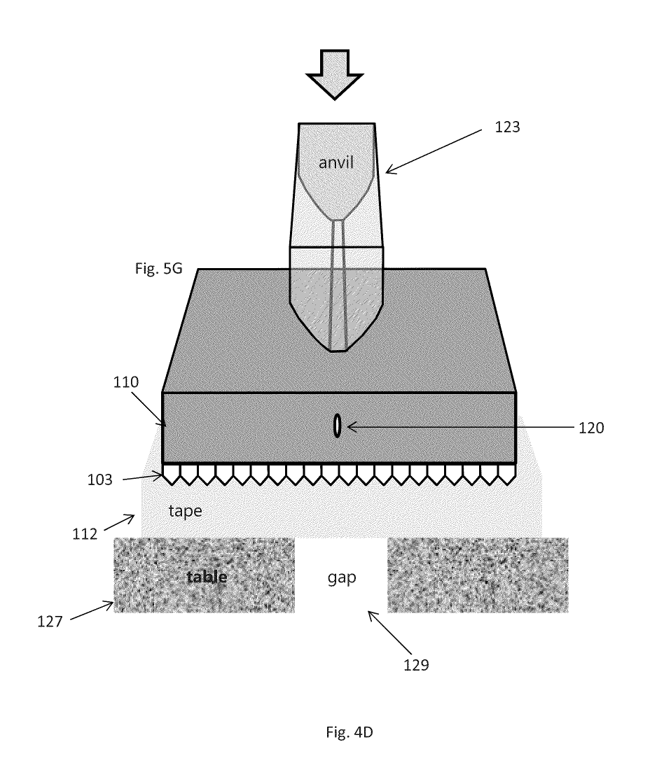

A laser defect generation and dicing technique known as Stealth Scribing™, enables the singulation of die shapes without symmetry as illustrated in FIG. 3B. The Stealth Scribing™ processes is illustrated in FIGS. 4A-D. The semiconductor device layers 103, such as LED layers, are formed on the front side 110F of a wafer 110, as shown in FIG. 4A. As illustrated in FIGS. 4A and 4B, the wafer is thinned and then mounted on a tape 112, front side (device side) 110F down. The smooth back side 110B of the wafer 110 is exposed.

Stealth Scribing™ involves a laser focused to an interior point in a wafer 110, resulting in a pattern defects 120 at the point of focus of the laser, as shown in FIG. 4A. As illustrated in FIG. 4A, two lasers, a guide laser 114G and a scribe laser 114S are typically used. The guide laser 114G measures the vertical height of the wafer 110 relative to the reflected laser light with a detector by reflecting light 116 off the smooth back surface 110B of the wafer 110. This measurement is fed back to the scribing laser 114S, which follows the guide laser 114G and focuses its energy at a consistent plane 118 inside the wafer 110. Preferably, the substrate is transparent to the scribing laser 114G. In an embodiment, the substrate is sapphire and the scribing laser 114S operates at a wavelength of approximately 532 nm.

The scribe laser 114S is rastered around the wafer 110 in x-y locations, writing the shape of the LED dies 102 shown in FIG. 4C by placing defects 120 (illustrated in FIG. 4A) along the lines where the dies 102 will be broken. After laser “scribing” (i.e., writing) a pattern of defects 120 into the wafer 110, there is a pattern 122 of defects 120 within the wafer 110, but the wafer 110 is still whole. The defects 120 are typically not be visible to naked eye on the wafer 110.

As illustrated in FIG. 4D, the LED dies 102 are singulated by pressing on the back of the wafer 110 with an anvil 123. Preferably, the wafer is located on a table 127 or other suitable surface having a gap 129 opposite the anvil 123.

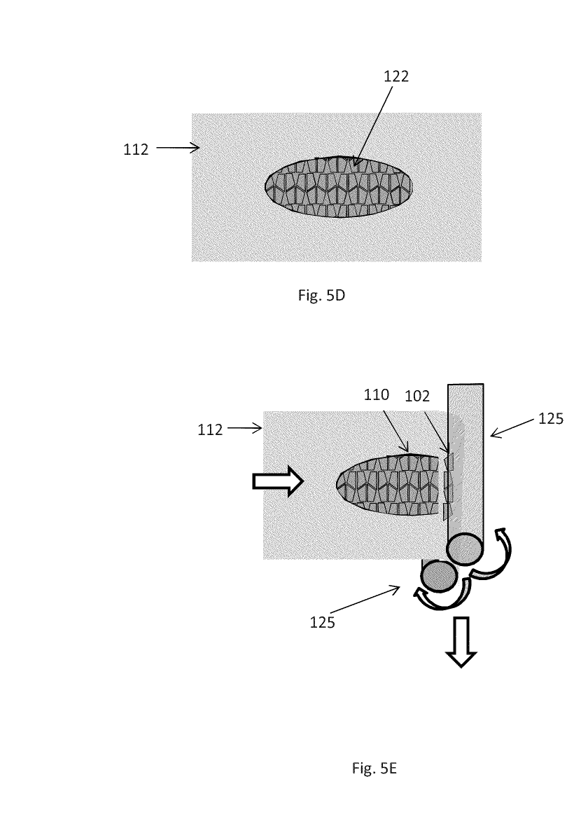

FIG. 6 is a photograph of a singulated die made according to the above method. The plane 118 of defects 120 is clearly visible in the photograph.

Thus, as described above, Stealth Scribing™ involves the application of internal defects to a wafer by laser focusing, and then anvil breaking the wafer along the lines of defects. Stealth Scribing™ uses preferred crystalline orientations for cleaving as there is still a minimum force needed for anvil breaking to break the wafer. “Preferred crystalline orientations” means there are certain orientations that will cleave preferential to other non-preferred orientations.

In one embodiment method of the present invention, the present inventors realized that etching of the continuous compressive stress layer which is uniformly compressively stressing the substrate, raises the local stress at etched grooves, which aids the dicing process after generating a defect pattern in the substrate using a laser. For example, a III-nitride buffer layer, such as a GaN buffer layer, on a sapphire substrate may be selectively etched to form street grooves which expose the substrate, creating local areas of increasing stress. Increasing the local stress decreases the force needed to break the substrate. Internal defects are then applied using the laser, as described above. Because of the increased local stress, the substrate can be broken with less force and can theoretically break in patterns inconsistent with the sapphire crystal preferred cleaving orientation.

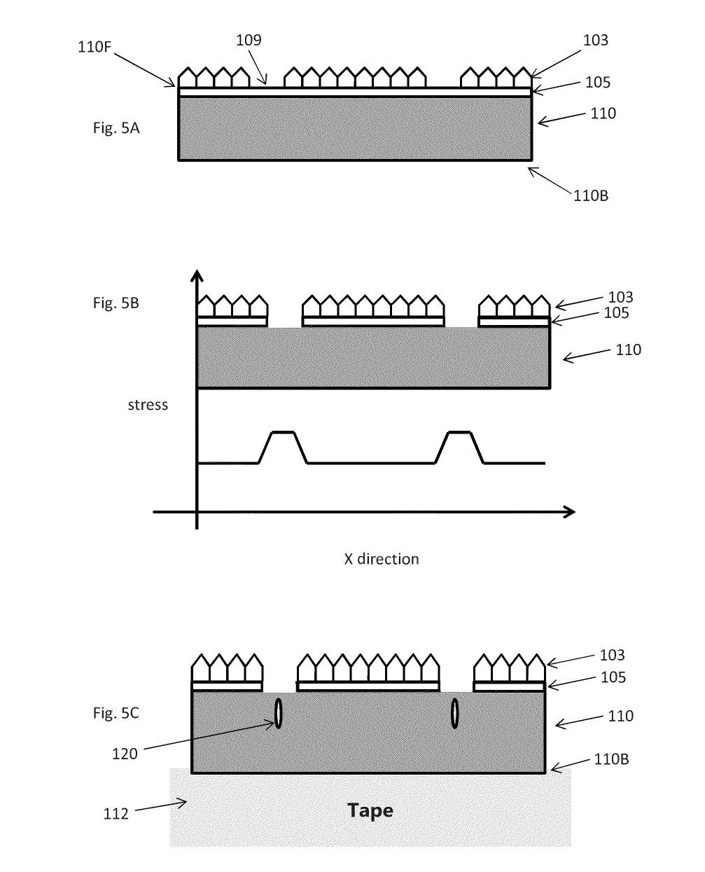

In one embodiment, the method of dicing the substrate shown in FIGS. 5A-5E includes depositing a continuous first layer 105, such as a GaN buffer layer, over the substrate 110, such as a sapphire wafer. The first layer 105 imparts a compressive stress to the substrate.

The method also includes etching grooves 109 in the first layer 105 to increase local stress at the grooves compared to stress at the remainder of the first layer located over the substrate, as shown in FIG. 5B. The step of etching grooves 109 comprises etching street grooves in inactive regions through the LEDs (i.e., LED layers) 103 and through the first layer 105 to expose the substrate and to define a pattern of individual LED dies on a first side of the substrate.

The method also includes generating a pattern 122 of defects 120 in the substrate with a laser beam, as shown in FIGS. 5C and 5D. The location of the defects 120 in the pattern 122 of defects substantially corresponds to a location of at least some of the grooves 109, and preferably all of the grooves, in the in the first layer 105. The street grooves 109 and the pattern 122 of defects 120 mimic a pattern of individual LED dies 102.

Finally, the method includes applying pressure to the substrate to dice the substrate along the grooves, as shown in FIG. 5E. The pressure may be applied by roll breaking using roller(s) 125 rolled on the substrate 110 to form LED dies 102.

Specifically, as illustrated in FIG. 5A, after fabricating the GaN buffer layer 105 and LED layers 103, either planar or nanowire, on the front side 110F of the substrate (e.g., sapphire wafer) 110, street grooves 109 are etched through the LED layers 103 and the buffer layer 105 down the surface 109 of the wafer 110 (the front 110F or device side of the wafer 110).

As illustrated in FIG. 5B, the compressive stress due to the continuous layer on the substrate, e.g. GaN on sapphire, results in peak stress concentrated in the streets 109 in the GaN buffer layer 105. This concentrated stress in the streets 109 aids in singulating the LED dies 102 in a controlled manner and reduces loss caused by cracks that meander away from the streets 109 and damage adjacent dies 102.

The wafer 110 is then thinned and mounted with the back side 110B onto a tape 112 or another support, as shown in FIG. 5C, which keeps the singulated dies 102 from scattering once they are singulated. Laser damaged regions (i.e., defects) 120 may be introduced into the wafer 110 with a laser as described above. Damaged regions 120 may be introduced with the laser either through the top (device) side 110F or the bottom (back) side 110B of the wafer 110. The pattern 122 of defects 120 preferably comprises a region of defects located less than 10 microns below a surface of the substrate 110.

The patterns 122 of defects shown in FIG. 5D are for illustration purposes only. Other patterns may be produced as desired. The pattern 122 illustrated in FIG. 5D results in LED dies 102 that are asymmetric and/or are differently shaped and/or differently sized, while the pattern 122 illustrated in FIG. 4C results in symmetrically shaped LED dies 102. The wafer 110 is weakened in the locations that define the shape of the LED dies 102.

The wafer 110 is then subjected to roll breaking with rollers 125, as shown in FIG. 5E. In an embodiment, two counter rotating rollers are used to singulate the LED dies 102. The substrate 110 may cleaved along a non-preferred crystalline cleaving orientation during the step of applying pressure to the substrate to dice the substrate along the grooves 109. With this method, LED dies 102 with symmetric and asymmetric die shapes can be made as shown in FIGS. 4D and 5E.

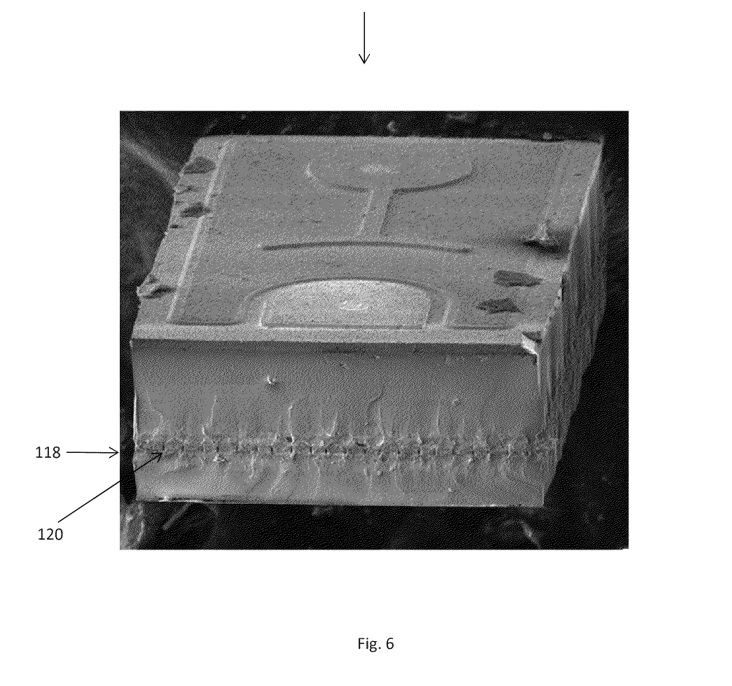

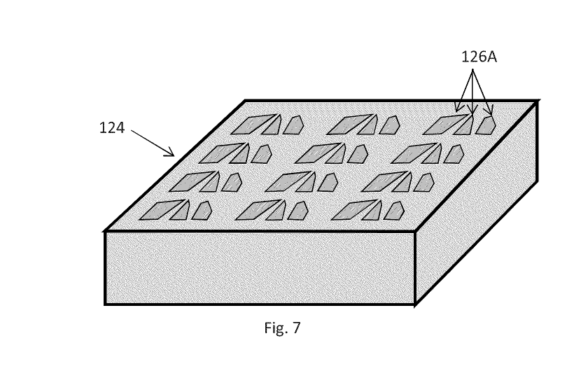

FIGS. 7-11 illustrate submounts 124 according to other embodiments. In an embodiment, the submount 124 is fabricated with standard metal interconnects, described in more detail below, prior to attaching the dies 102. In an embodiment described in more detail below, the submount 124 includes symmetrical tubs 126 in which the LED dies 102 are located. In the embodiment illustrated in FIG. 7, the submount 124, includes asymmetrical tubs 126A with the same asymmetric shape as the asymmetrical LED dies 102A (discussed above). Several different asymmetric tub 126A shapes can be etched into the submount 124 which allows for several different LED dies 102A to be integrated into the submount 124, as illustrated in FIG. 8. In an embodiment, the submount 124 is made of silicon.

Another embodiment is drawn to a method of integrating asymmetrical LED dies 102A discussed above into a submount 124 having asymmetrical tubs 126A as illustrated in FIG. 7. Conventional “pick and place” methods of locating LED dies 102 in the tubs 126 of a submount 124 require either people or robots to individually place the LEDs into the tubs 126. The following embodiments describe methods of locating LED dies into tubs of a submount without the use of people or robots to individually pick up and place the LED dies into the tubs 126 of the submount 124. In an embodiment, the individual asymmetrical LED dies 102A are dispensed onto the submount 124 while the submount is vibrated. This agitation aids in the placement of the correct asymmetrical LED dies 102A fitting into the corresponding asymmetrical tub 126A. Preferably, only one combination of die and tub is possible. Also, the x-y asymmetry assures the correct side of the asymmetrical LED die 126A is “face up” (else the asymmetrical LED die 126A does not fall into the asymmetrical tub 126A). In an embodiment, when all the asymmetrical LED dies 126A are placed in the correct asymmetrical tub 126A, heat is applied to the submount 124 for eutectic bonding. Eutectic bonding is a metallurgical reaction between two different metals with heating in which the metal form an alloy at a temperature below the melting temperature of either of the metals. In an embodiment, a film of one metal is deposited on the bottoms of the asymmetrical LED dies 126A and a film of the other metal is deposited in the asymmetrical tubs 126A. An example of a suitable eutectic reaction for die attachment is Au—Sn. Gold and tin form an alloy upon heating to approximately 280° C.

Another embodiment is drawn to a method of sequentially locating a plurality of differently shaped and/or differently sized light emitting diodes (LED) die 102 in a submount 124. The method includes depositing first shaped and/or sized LED die 102 on a surface of the submount 124. The submount includes a plurality of first shaped and/or sized tubs 126 that correspond in shape and/or size with the first shaped and/or sized LED die 102 of the plurality of differently shaped and/or sized LED die 102. The method further includes vibrating the submount 124 to locate the first shaped and/or sized LED die 102 in the first shaped and/or sized tubs 126. After the step of vibrating the submount 124 to locate the first shaped and/or sized LED die 102 in the first shaped and/or sized tubs 126, second shaped and/or sized LED die 102 of the plurality of differently shaped and/or sized LED die 102 which have a different shape or size from the first shaped and/or sized LED die 102 are deposited on the surface of the submount 124. The submount 124 includes a plurality of second shaped and/or sized tubs 126 corresponding in shape and/or size with the second shaped and/or sized LED die 102 of the plurality of differently shaped and/or sized LED die 102. Then, the submount 124 is vibrated again to locate the second shaped and/or sized LED die 102 in the second shaped and/or sized tubs 126.

In an embodiment, the method further includes depositing a third shaped and/or sized LED die 102 which have a different shape and/or size from the first and/or second shaped and/or sized LED die 102 on a surface of the submount 124 after the step of vibrating the submount 124 to locate the second shaped and/or sized LED die 102 in the second shaped and/or sized tubs 126. The submount 124 includes a plurality of third shaped and/or sized tubs 126 corresponding in shape and/or size with the third shaped and/or sized LED die 102. The submount 124 is vibrated again to locate the third shaped and/or sized LED die 102 into the third shaped and/or sized tubs 126.

Vibration of the first, second and third shaped and/or sized LED die 102 can be performed sequentially for symmetrically or asymmetrically shaped LED die 102. Vibration of the first, second and third shaped and/or sized LED die 102 can be performed simultaneously if the LED dies 102 and the tubs 126 are asymmetrically shaped such that the first asymmetrically shaped LED die 102 only fit into correspondingly first shaped tubs 126, the second asymmetrically shaped LED die 102 only fit into correspondingly second shaped tubs 126 and the third asymmetrically shaped LED die 102 only fit into correspondingly third shaped tubs 126.

In an embodiment, the first shaped and/or sized LED die 102 include first color emitting LED die 102, the second shaped and/or sized LED die 102 include second color emitting LED die 102 different from the first color, and the third shaped and/or sized LED die 102 include third color emitting LED die 102 different from the first and the second colors. The method may further include wire bonding the first, second and third shaped and/or sized LED die 102 to the submount 124. The method may also further include encapsulating the LED dies 102.

In an embodiment, the location of the LED dies 102 into the tubs 126 can be assisted by application of a magnetic or electromagnetic force. For example, a magnetic material may be deposited on the bottom surface of the LED dies 102 and a magnetic field selectively applied under tubs 126 to be filled with the LED dies 102. If all of the differently shaped/sized LED dies 102 are to be located in the tubs 126 at the same time (i.e. simultaneously), a magnetic field may be applied under all of the tubs 126 in the submount 124. If the LED dies 102 are to be located in the tubs 126 sequentially by shape and/or size, a magnetic field may be selectively applied only under those tubs 126 corresponding to the LED dies 102 currently being located (e.g. first locating larger size dies with magnetic assistance, then locating intermediate size dies with magnetic assistance and then locating smaller size dies with magnetic assistance).

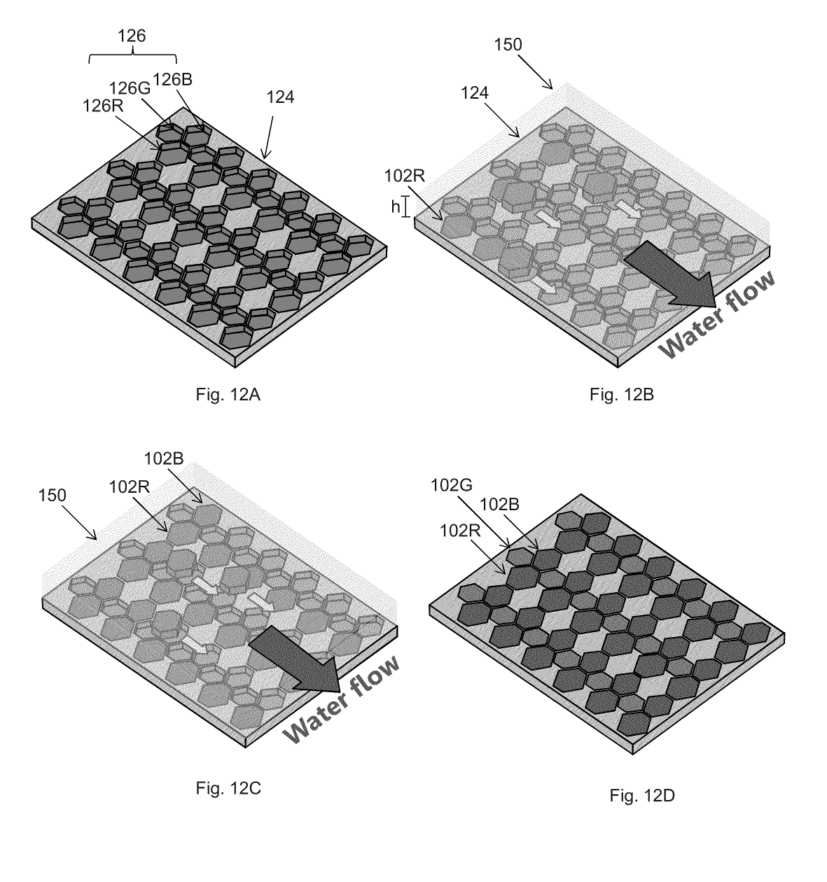

FIGS. 12A to 12D are perspective views illustrating a method of locating LED die 102 in a submount according to an embodiment. In this embodiment, the submount 124 includes tubs 126 with different sizes and/or shapes. FIGS. 12A-12D illustrate a submount 124 that includes three different sizes of symmetrical tubs 126R, 126B and 126G to fit respective red, blue and green LED die 102R, 102B and 102G of different sizes but the same shapes. However, any number of different tub sizes and/or shapes may be included, such as 2-10, for example 4-8 to fit 2-10, such as 4-8 different LED die sizes and/or shapes. As used herein, a different size includes a different width, a different length and/or a different area.

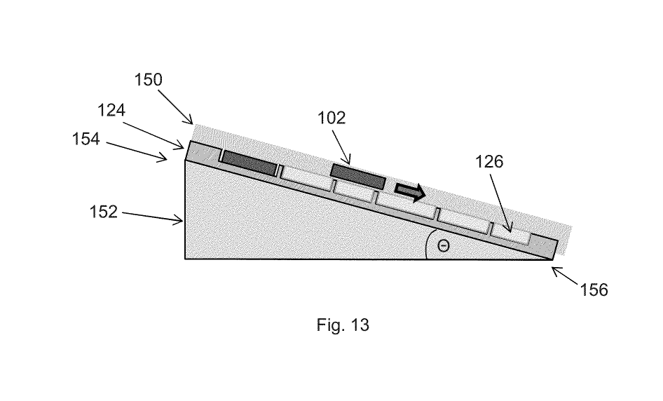

Preferably, the submount 124 is tilted at an angle such that the submount 124 is configured non-horizontally with a high end and a low end. This may be accomplished, for example, by placing the submount 124 on wedged shaped platform 152 that has a high end 154 and a low end 156, as illustrated in FIG. 13. The angle θ of the tilt may be between 10 and 35 degrees, such as 15-25 degrees.

In the step illustrated in FIG. 12B, LED die 102 of a first size suspended in a fluid (e.g., liquid) 150 are provided to the submount 124. Since the submount is tilted, liquid 150 flow commences from the high end 154 of the submount to the opposite low end 156. If there are three tub sizes in the submount, then the largest LED die that will fit in only the largest size tubs are first introduced into the flow. For example, red emitting LED die 102R having the largest size are suspended in the fluid 150 first. The die 102R remain suspended in the fluid flowing over the submount until each respective die 102R drops into one of the largest sized tubs 126R. The die 102R are too large to fit into the smaller sized tubs 126B or 126G. In other words, as the die 102R travel the length of the submount, each red emitting LED die 102R will be placed into a tub 126R that fits it. The larger die 102R will “pass over” the tubs 126B and 126G that are too small for the die 102R. This process locates the LED die 102R of the largest size in the corresponding tubs 126R to fill all of the available tubs 126R.

As illustrated in FIG. 12C, after locating LED die 102 of the first size, such as red emitting LED die 102R in the corresponding tubs 126R, LED die 102 of a second, smaller size, such as blue emitting LED die 102B, are suspended in the fluid 150 flowing from the high end 154 of the submount 124 to the low end 156 to assist in locating the second, medium sized LED die 102B into the corresponding medium size tubs 126B. This step is continued until all of the medium sized tubs 126B are filled with the medium sized die 102B.

After the LED die 102B of the second size are located in their corresponding tubs 126B, LED die 102 of a third size, such as the smallest size green emitting LED die 102G are suspended in the fluid 150 flowing from the high end 154 of the submount 124 to the low end 156. This assists in locating the smallest sized LED die 102G into the corresponding smallest size tubs 126G, as shown in FIG. 12D.

The process of sequentially providing LED die 102 of different sizes to the high end of the submount 124 continues until all of the LED die 102 are located in their corresponding tubs 126 in the submount 124, as illustrated in FIG. 12D. In an embodiment, the LED die 102 with the largest size are provided first, followed by providing successively smaller LED die 102. In this manner, smaller LED die 102 will not unintentionally be located in tubs 126 sized for larger LED die 102. While die and tubs of different size are illustrated in FIGS. 12B-12D, die and tubs of different shape or of different shape and size may be used. Furthermore, while the red emitting LED die 102R are described above as having the largest size, different color (e.g., green or blue) LED die may have the largest size instead. Likewise, any color emitting LED die may have the medium or the smallest size.

Once all of the tubs 126 are filled with LED die 102, the submount 124 may be dried. After drying, the LED die 102 may be joined to the submount 124 by eutectic bonding, as described above. After electrically connecting the LED die to the contacts and leads as described in the previous embodiment, the entire submount 124 containing the plurality of LED die is coated (e.g., screen printed, etc.) with a transparent passivation layer, such as a silicone layer to passivate the die and enhance light output of the device.

Another embodiment is drawn to a method of sequentially or simultaneously locating a plurality of differently asymmetrically shaped light emitting diode (LED) dies 102A in a submount 124. The method includes providing the plurality of differently asymmetrically shaped LED die 102A suspended in a fluid flowing across the submount 124 to locate the plurality of differently asymmetrically shaped LED die 102A in a plurality of differently asymmetrically shaped tubs 126A corresponding in shape with each shape of each set of the plurality of differently asymmetrically shaped LED die 102A. In an embodiment, the plurality of differently asymmetrically shaped LED die 102A comprise a first plurality of differently asymmetrically shaped LED die 102A and a second plurality of differently asymmetrically shaped LED die 102A which have a different asymmetric shape than the first plurality of differently asymmetrically shaped LED die 102A. The submount 124 comprises first tubs 126A in a surface of the submount 124 having a first asymmetric shape corresponding in shape with the first plurality of asymmetrically shaped LED die 102A and second tubs 126A in a surface of the submount 124 having a second asymmetric shape corresponding in shape with the second plurality of asymmetrically shaped LED die 102A.

In an embodiment, the plurality of asymmetrically shaped LED die 102A comprise a third plurality of asymmetrically shaped LED die 102A having a different shape than the first or second plurality of asymmetrically shaped LED die 102 and the submount 124 comprises third tubs 126A in the surface of the submount 124 having a third asymmetric shape corresponding in shape with the third plurality of asymmetrically shaped LED die 102A. In an embodiment, the first plurality of asymmetrically shaped LED die 102A comprise first color emitting LED die, the second plurality of asymmetrically shaped LED die 102A comprise second color emitting LED die different from the first color and the third plurality of asymmetrically shaped LED die 102A comprise third color emitting LED die different from the first and the second colors.

In an embodiment, the first plurality of LED die 102A do not fit into the second or the third tubs 126A and pass over the second and the third tubs 126A while suspended in the fluid. The second plurality of LED die 102A do not fit into the first or the third tubs 126A and pass over the first and the third tubs 126A while suspended in the fluid. The third plurality of LED die 102A do not fit into the first or the second tubs 126A and pass over the first and the second tubs 126A while suspended in the fluid.

The LED die can be any size or shape, but will generally be a variation of a thin plate, where the thickness of the plate is much less than the length(s) and width(s). The LED die 102 are introduced to the fluid 150 flow with the thinnest dimension of the die orthogonal to the plane of the submount 124 containing the tubs 126. The fluid 150 aids in moving the LED die 102 down the submount 124, assisting in locating the LED die 102 in the tubs 126 in the submount 124 as the LED die 102 move down the submount 124. Thus, as the LED die travel in the fluid flow, the fluid (e.g., water) 150 flow level is kept to a minimum, such as to the minimum amount needed to assist the gravity-assisted fall of the die. The fluid flow will also maintain contact between the submount, the fluid, and the LED die, so the LED die will not leave the fabrication process through the capillary action.

In an embodiment, the height h of the fluid is less than a thickness of the plurality of LED die 102. Preferably, the fluid 150 flows across the submount 124 with laminar flow. In this manner, the LED die 102 are less likely to flip or tumble as then slide down the submount 124. In an embodiment, the fluid is water. However, any fluid could be used such as methanol, ethanol or combinations thereof with or without water.

One embodiment provides a method of locating a plurality of light emitting diode (LED) dies 102 in a submount 124. The method includes providing a submount 124 having a plurality of first tubs 126 having at least one of a first tub shape or a first tub size and a plurality of second tubs 126 having at least one of a second tub shape or a second tub size different from the respective first tub shape or first tub size. The method also includes providing a first plurality of LED die 102 having at least one of a first die shape or first die size to locate across the submount 124 the first plurality of LED die 102 in the first plurality of tubs 126 but not in the second plurality of tubs 126, and providing a second plurality of LED die 102 having at least one of a second die shape or second die size to locate across the submount 124 the second plurality of LED die 102 in the second plurality of tubs 126 but not in the first plurality of tubs 126. That is, the size and/or shape of the LED dies 102 and the corresponding tubs 126 may be selected such that only LED dies are located in tubs with respective corresponding size and/or shape. Different embodiments of locating LED dies 102 into the appropriate tubs 126 are summarized in Table I below:

TABLE 1

| | Vibration | Flowing Fluid |
|---|---|---|
| Sequential location | Different light emitting dies | Different light emitting dies |
| | may be: | may be: |
| | Asymmetric or symmetric; | Asymmetric or symmetric; |
| | Have different size or different | Have different size or different |
| | shape (symmetric or | shape (symmetric or |
| | asymmetric); and/or | asymmetric); and/or |
| | May have magnetic or | May have magnetic or |
| | electromagnetic assistance; | electromagnetic assistance; |
| | and/or | and/or |
| | | Submount may be vibrated in |
| | | addition to flowing the fluid to |
| | | assist in LED die placement. |
| Simultaneous location | Different light emitting dies | Different light emitting dies |
| | may be: | may be: |
| | May have a shape that does | May have a shape that does |
| | not fit into other shaped tubs | not fit into other shaped tubs |
| | but only fits into its own tub | but only fits into its own tub |
| | shape; | shape; |
| | Have different size or different | Have different size or different |
| | shape; and/or | shape; and/or |
| | May have magnetic or | May have magnetic or |
| | electromagnetic assistance; | electromagnetic assistance; |
| | and/or | and/or |
| | | Submount may be vibrated in |
| | | addition to flowing the fluid to |
| | | assist in LED die placement. |

In an embodiment, the metal interconnects are fabricated in the submount 124 before integrating the asymmetrical LED dies 102A. In this embodiment, the asymmetrical LED dies 102A can be wire bonded to the pad on the metal interconnects, as described in more details below. Wire interconnects on the submount 124 may be fabricated by standard silicon processing techniques prior to assembly of the LED device 100. After the asymmetrical LED dies 102A are affixed to the submount 124, the front side of the dies 124 may be electrically connected to the metal interconnects in the submount 124 by a direct write process, such as ink jet deposition of metal interconnects. After metal connection from the LED dies 102A to the submount, an encapsulant may be deposited over the LED dies 102A.

Alternatively, if there are no interconnects on the submount 124, the interconnects may and insulating layers be deposited to connect the asymmetrical LEDs 102A to the submount 124 by direct write via inkjet printing of metal and deposition and patterning of a photoactive polyimide material, respectively. That is, in this embodiment, all of the metal interconnects are fabricated after the LED dies 102A are assembled into the submount 124. Multiple layers of metal interconnects may be made by a direct write process using ink jet deposition of metal connects or micro dispensing of metal in a solvent and deposition and patterning of a photoactive polyimide that acts as an insulator between the layers of metal interconnects.

As in the previous embodiment, after the asymmetrical LED dies 102A are connected to the submount 124, encapsulant can be deposited over the asymmetrical LED dies 102A with standard encapsulant techniques.

The above described fabrication processes are more cost effective to assemble devices with large numbers of LED dies 102A than existing methods involving printed circuit boards which require individual placement and attachment of LED dies 102, and individual wire bonding of the individual LED dies 102 to metal interconnects on the printed circuit board.

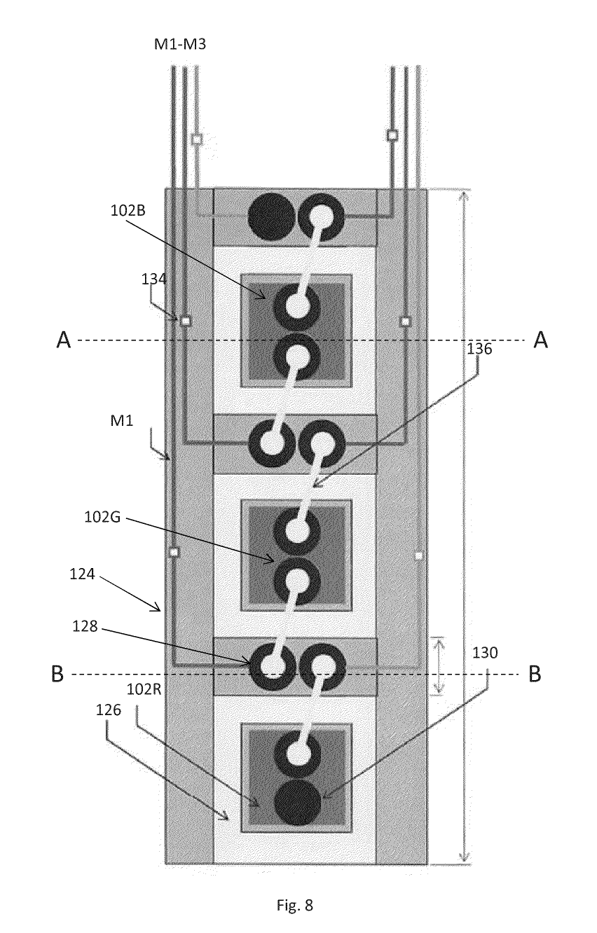

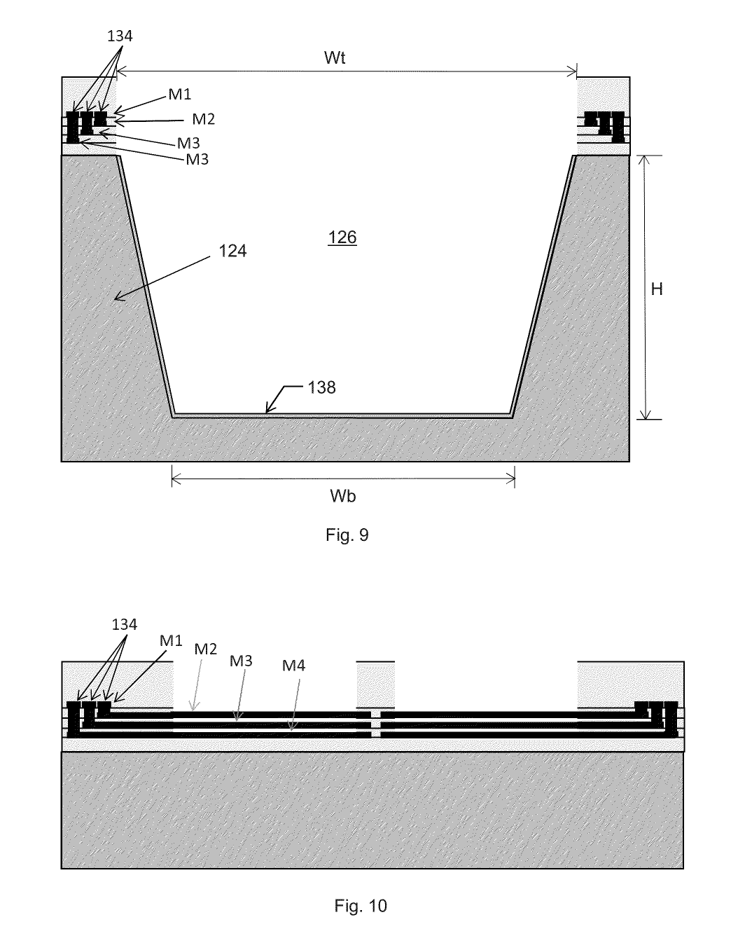

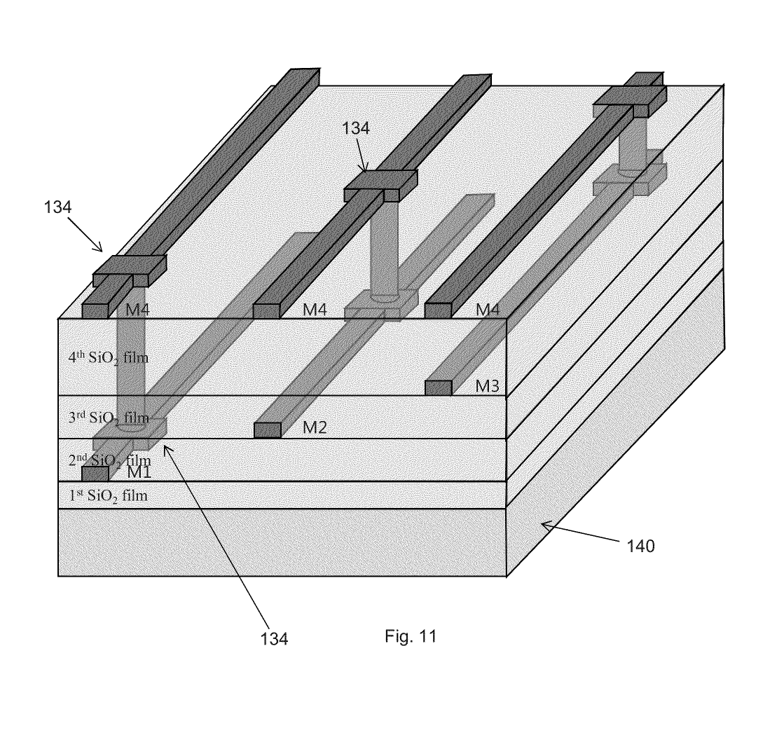

FIGS. 8-11 illustrate a silicon submount 124 suitable for use with an integrated back light unit according to another embodiment. Features of the submount 124 include integrated multilevel interconnect fabrication with the submount, selective Ni/Ag plating of the tubs onto highly doped Si, and deep Si etch of tubs over existing multilevel interconnect stacks. FIG. 8 is a plan view of the submount 124 while FIGS. 9 and 10 are cross-sectional views of the submount 124 through lines AA and BB, respectively. The cross section illustrated in FIG. 9 is through one of the tubs 126 prior to attachment of an LED die 102. The cross section illustrated in FIG. 10 is through a pad area between tubs 102. FIG. 11 is a three dimensional cut away view illustrating a portion of the submount of FIG. 8.

Each symmetric tub 126 is configured to hold an LED die 102. As illustrated in FIG. 9, the tubs 126 are preferably tapered. That is, the bottom of the tub 124 in which each LED die 102 is located has a width w_{b} equal to or slightly larger than the width of the LED die 102 while the top of the tub 126 has a width wₜ larger than w_{b}. The top width wₜ is larger than w_{b} to aid in locating the LED dies 102 into the tubs 126.

In the embodiment illustrated in FIG. 8, the submount 124 includes three symmetric tubs 126. In an embodiment, a first tub 126 includes a red LED die 102R, a second tub 126 includes a green LED die 102G and the third tub includes a blue LED die 102B. However, all of the tubs 126 may include LED dies that emit the same color of light. Further, the submount 124 is not limited to three tubs 126. The submount 124 may have any number of tubs 126, such as 2-72, such as 3-60 tubs, such as 6-48 tubs. In an embodiment, a segment is defined as three tubs 126, typically including one red LED die 102R, one green LED die 102G and one blue LED die 102B. The submount may include 1-24 segments, such as 2-20 segments, such as 3-16 segments.

As illustrated in FIG. 8, the submount 124 includes metal pads 128 between the tubs 126 for wire bonding. By placing the metal pads 128 between the tubs 126 rather than along the sides as in conventional submounts, the width of the submount can be reduced. Each LED die 102 includes corresponding bond pads 130. Wire bonds 136 connect the metal pads 128 on the submount 124 to the corresponding bond pads 130 on the LED dies 102.

Also included in the submount 124 are metal lines M1-M4 which are used to supply current to the LED dies 102. While four lines are shown, other number of lines may be used. As illustrated in FIGS. 10 and 11, the metal lines M may be located in different levels within the submount 124 such that there are four levels M1, M2, M3, M4. The submount 124 also includes metal landing pads 134 with vias on top to bring power to the metal lines M1, M2, M3, M4. For example, lines M4 may be bus lines which provide current to electrode lines M1, M2, M3 which connect to the LED die. As illustrated, the metal landing pads 134 are square. However, the metal landing pads 134 may be circular, rectangular, hexagonal or any other suitable shape. Also illustrated in FIG. 9 is a metal film 138 lining the tub 126. The metal film 138 material (e.g., Au—Sn or Ni—Al) is selected to react with a second metal film (not shown) on the bottom of the LED dies 102 to form a eutectic bond as discussed above.

In an embodiment, the submount is made of silicon and includes integrated interconnects for an integrated back light unit. In an embodiment:
1. Red, green, and blue LED dies 102R, 102G, 102B are 6-12, such as 8-10 mils square, e.g., a maximum of 210 μm square. However, in alternative embodiments, other size LED dies 102 may be used;
2. A 365 nm contact lithography stepper may be used to produce interconnect line/spaces of 5 μm/5 μm;
3. The tubs 126 may be 200-400 μm deep, such as 300 μm deep with 65-85 degree sloped sidewalls, such as 80 degree sidewalls;
4. The tubs 126 preferably have reflectors (i.e., film 138) on the bottom and sidewalls;
5. The street widths are less than 150 μm, such as 100 μm, if conventionally scribed and may be less if stealth scribed;
6. Al may be used as a hard mask when deep etching a Si submount. In alternative embodiments, a more refractory metal than Si, such as Cr, Ti, TiN, TiW, or W may be used on top of Al to resist the Si etch.

In an embodiment, the submount 124 may be 530 μm wide and 33,120 μm long, not including pads to contact to the outside for power. Add 300 μm to the length for the 6 pads that will attach to the outside world and the submount 124 length is 33,420 μm. On a 200 mm Si wafer with 3 mm edge exclusion, this enables 1355 submounts 124 per wafer.

An embodiment is drawn to a method of making the above submount 124. One aspect of the embodiment of the method includes the following process flow:
1. Starting material: mechanical grade highly doped 200 mm Si wafers;
2. Deposit or grow 1000 Å SiO₂ film on the Si wafer; thickness can be anywhere from 200 Å to 10 μm. Alternately, photoactive polyimide can be used in place of the SiO₂, or other dielectrics, such as low-k SiCOH, SiN, Al₂O₃, etc dielectrics.
3. Pattern 300 Å Ti/1 μm Al (thin Ti for adhesion) lines on the SiO₂ by a lift off technique or mask and etch (metal 1, or M1); thicknesses can be anywhere from 50 Å to 1 μm of Ti and 2000 Å to 3 μm Al. Alternately there can be an antireflective coating on top of Al, typically Ti, TiN, WN, or Cr;
4. Deposit a second SiO₂ film 1 micron thick on top of M1; thickness can be anywhere from 200 Å to 10 μm, although in general, it should scale with the thickness of the metal;
5. Deposit a second Ti/Al line, or M2, on top of the second SiO2 film;
6. Deposit a third SiO₂ film on top of M2;
7. Deposit a third Ti/Al film M3 on top of the third SiO₂ film;
8. Deposit a fourth SiO₂ film on top of M3;
9. Pattern the fourth oxide film and dry etch SiO₂ to open the vias and pads to M1, M2, & M3;
10. Deposit, pattern, and etch Ti/Al film M4 on top of the fourth SiO₂ film; with the pads to M1, M2, and M3 open, M4 will now connect to the lower metal layers. M4 is called the bus line(s). In an embodiment, there are 6 discrete interconnects in M4, allowing n and p connections to the red, green, and blue LEDs, respectively. The LED can be connected in series or parallel at the designer's discretion. If a via connects each die to the bus line, then all LED are connected in parallel. If there are only vias at the first and last (e.g., 72^{nd}) LED, then the LED are connected in series. Any other combination is also possible (e.g. connect every 3^{rd} red LED, so that there are 3 in series, and that group of 3 is connected in parallel to 8 other groups of 3);
11. Deposit a fifth SiO₂ film on top of M4; This final SiO₂ film forms the passivation;
12. Pattern the tubs, and proceed to dry etch the SiO₂;
13. Dry etch 300 μm deep tubs into the Si wafer. The tubs can be skipped (0 μm deep, or can be anywhere from 100 to 500 μm deep);
14. After Si etch, electroplate Ni/Ag into the exposed conductive Si. Typical Ni/Ag thicknesses are 300 Å Ni/2000 Å Ag. Nickel thickness can range from 50 Å to 5000 Å, and silver thickness can range from 500 Å to 5 μm;
15. Singulate LED die using sawing or any of the other singulation methods described herein;
16. Die attach by eutectic bonding or by epoxy or silicone adhesive, followed by curing of same;
17. Wire bond, e.g. with Au wire bonds;
18. Encapsulate, e.g. using silicone, which can alternately have a phosphor powder embedded in it, converting the LED's light from one wavelength to another.

Both Al and SiO₂ have excellent resistance erosion during silicon etch. When these materials are combined with a thick photoresist and time multiplexed deep silicon etch techniques, there is sufficient margin to etch 300 μm of silicon without significant erosion of features that are masked from the etch. Electroless nickel plating of silicon is an established technique to metallize silicon. Subsequent silver plating the nickel is also an established technique, and allows for the selective plating of the tubs while not plating the SiO₂-covered areas. Silicon submounts have advantages in wafer level packaging (high productivity fabrication), superior heat sink capability of silicon compared to more standard composite packages, and better thermal expansion match between silicon and sapphire compared to sapphire and composite packages.

Although the foregoing refers to particular preferred embodiments, it will be understood that the invention is not so limited. It will occur to those of ordinary skill in the art that various modifications may be made to the disclosed embodiments and that such modifications are intended to be within the scope of the invention. All of the publications, patent applications and patents cited herein are incorporated herein by reference in their entirety.

1. A method of locating a plurality of light emitting diode (LED) dies in a submount, comprising:
providing a submount having a first tubs having at least one of a first tub shape or a first tub size and second tubs having at least one of a second tub shape or a second tub size different from the respective first tub shape or first tub size;
providing a first plurality of LED die having at least one of a first die shape or first die size to locate across the submount the first plurality of LED die in the first tubs but not in the second tubs; and
providing a second plurality of LED die having at least one of a second die shape or second die size to locate across the submount the second plurality of LED die in the second tubs but not in the first tubs.

2. The method of claim 1, wherein the first LED die shape or size corresponds to the first tub shape or size, and the second LED die shape or size corresponds to the second tub shape or size.

3. The method of claim 1, wherein each of the plurality of first LED die is located in a respective one of the first tubs and each of the second LED die is located in a respective one of the second tubs.

4. The method of claim 1, wherein the first plurality of LED die fit into respective first tubs but not into the second tubs due to the first die shape or size not fitting into the second tubs.

5. The method of claim 4, wherein the second plurality of LED die fit into respective second tubs but not into the first tubs due to the second die shape or size not fitting into the first tubs.

6. The method of claim 4, wherein the second plurality of LED die fit into second tubs and first tubs but are not located in the first tubs because all of the first tubs are filled with the first plurality of LED die.

7. The method of claim 1, further comprising vibrating the submount to locate the first plurality of LED die in the first tubs and the second plurality of LED die in the second tubs.

8. The method of claim 7, wherein vibrating the submount comprises:
a first step of vibrating the submount to locate the first plurality of LED die in the first tubs, wherein the first step of vibrating is performed after providing the first plurality of LED die but prior to providing the second LED die; and
a second step of vibrating the submount to locate the second plurality of LED die in the second tubs, wherein the second step of vibrating is performed after locating the first plurality of LED die in the first tubs and after providing the second LED die.

9. The method of claim 7, wherein vibrating the submount is performed after providing both the first and second pluralities of LED die and the first plurality of LED die and the second plurality of LED die are simultaneously located in the respective first and second tubs.

10. The method of claim 9, wherein the first plurality of LED die have a first asymmetric shape, the second plurality of LED die have a second asymmetric shape, wherein the first asymmetric shape is different from the second asymmetric shape, the first tub shape corresponds in shape with the first asymmetric shape, the second tub shape corresponds in shape with the second asymmetric shape, only the first plurality of LED die fit in the first tubs, and only the second plurality of LED die fit in the second tubs.

11. The method of claim 1, further comprising flowing the first and second pluralities of LED die in a fluid across the submount to locate the first plurality of LED die in the first tubs and the second plurality of LED die in the second tubs.

12. The method of claim 11, wherein flowing the first and second pluralities of LED die across the submount comprises:
a first step of flowing to locate the first plurality of LED die in the first tubs, wherein the first step of flowing is performed after providing the first plurality of LED die but prior to providing the second LED die; and
a second step of flowing to locate the second plurality of LED die in the second tubs, wherein the second step of flowing is performed after locating the first plurality of LED die in the first tubs and after providing the second LED die.

13. The method of claim 11, wherein flowing the first and second pluralities of LED die across the submount is performed after providing both the first and second pluralities of LED die and the first plurality of LED die and the second plurality of LED die are simultaneously located in the respective first and second tubs.

14. The method of claim 13, wherein the first plurality of LED die have a first asymmetric shape, the second plurality of LED die have a second asymmetric shape, wherein the first asymmetric shape is different from the second asymmetric shape, the first tub shape corresponds in shape with the first asymmetric shape, the second tub shape corresponds in shape with the second asymmetric shape and wherein only the first plurality of LED die fit in the plurality of first tubs and only the second plurality of LED die fit in the plurality of second tubs.

15. The method of claim 1, further comprising locating the first and second pluralities of LED die with magnetic or electromagnetic assistance.

16. The method of claim 1, wherein the first die shape is different from the second die shape.

17. The method of claim 1, wherein the first die size is different from the second die size.

18. The method of claim 1, wherein the first die shape and the first die size are different from the second die shape and the second die size.

19. The method of claim 1, wherein the submount comprises integrated interconnects fabricated in the submount prior to providing the first and the second plurality of LED die.

20. The method of claim 1, further comprising after the step of providing the second plurality of LED die, providing a third plurality of LED die having at least one of a third die shape or third die size to locate across the submount in third tubs.

21. The method of claim 20, wherein the third tubs have at least one of a third tub shape or a third tub size, and wherein the third plurality of LED die are not located in the first or second tubs.

22. The method of claim 21, wherein:
the first plurality of LED die have a larger size than the second plurality of LED die;
the second plurality of LED die have a larger size than the third plurality of LED die;
the first tubs have a larger size than the second tubs; and
the second tubs have a larger size than the third tubs.

23. The method of claim 21, wherein:
the first plurality of LED die have a different shape from the second plurality of LED die;
the second plurality of LED die have a different shape from the third plurality of LED die;
the first tubs have a different shape from the second tubs; and
the second tubs have a different shape from the third tubs.

24. The method of claim 21, wherein:
the first plurality of LED die comprise first color emitting LED die;
the second plurality of LED die comprise second color emitting LED die different from the first color; and
the third plurality of LED die comprise third color emitting LED die different from the first and the second colors.

25. The method of claim 1, wherein the first and second pluralities of LED die are provided without picking and placing individual LED die into the first and second tubs.

26-39. (canceled)

40. A light emitting diode device comprising a plurality of asymmetrically shaped light emitting diode (LED) dies located in a submount in a plurality of asymmetric tubs corresponding in shape with the asymmetrically shaped LED dies.

41. The device of claim 40, wherein red emitting LED dies have a first shape and are located in first shape tubs, green emitting LED dies have a second shape and are located in second shape tubs, and blue emitting LED dies have a third shape and are located in third shape tubs, and wherein the first, second and third shapes are different from each other.

42-73. (canceled)
